(19) United States
(12) Patent Application Publication
(10) Pub. No.: US 2011/0069546 A1
(43) Pub. Date: Mar. 24, 2011

(54) NONVOLATILE SEMICONDUCTOR MEMORY DEVICE

(75) Inventor: Yoshihisa WATANABE, Yokohama-shi (JP)

(73) Assignee: Kabushiki Kaisha Toshiba, Tokyo (JP)

(21) Appl. No.: 12/885,911

(22) Filed: Sep. 20, 2010

(30) Foreign Application Priority Data
Sep. 24, 2009 (JP) 2009-219089

(51) Int. Cl. G11C 16/04; G11C 16/12

(52) U.S. Cl. 365/185.03

(57) ABSTRACT

A nonvolatile semiconductor memory device according to an embodiment includes: a memory cell array including a plurality of memory cells to store N-value data (N being an integer equal to or larger than 3); and a writing circuit configured to repeatedly execute a writing cycle on a plurality of memory cells until data writing is finished. The writing circuit divides the pulse width of the writing pulse into a plurality of sections to change the pulse height among the sections such that the respective sections provide writing voltages for writing different target threshold levels, and brings the bit line connected to the memory cell to be written with any of the target threshold levels into a selected state synchronously to the section for applying the writing voltage for writing that target threshold level.

### CROSS REFERENCE TO RELATED APPLICATIONS

This application is based on and claims the benefit of priority from prior Japanese Patent Application No. 2009-219089, filed on Sep. 24, 2009, the entire contents of which are incorporated herein by reference.

### BACKGROUND

1. Field

Embodiments described herein relate generally to a nonvolatile semiconductor memory device.

2. Description of the Related Art

One type of EEPROM is NAND type flash memory. Owing to its memory cell configuration having a small unit cell area of about 4F² (F: minimum feature size), NAND type flash memory leads other nonvolatile semiconductor memories in suitability for miniaturization and large memory capacity. If multi-value storage technique of storing data of two bits or more in one memory cell is used, the memory capacity can be increased to double or higher without increase in the chip area.

Nowadays, NAND type flash memory is used as nonvolatile recording media of various portable gadgets. In such applications, improvement is required not only in the memory capacity but also in the access speed. Today, access speed of NAND type flash memory has come to greatly influence the access speed of the recording media. Here, a particular challenge is to improve the writing throughput.

In a writing operation of NAND type flash memory, an FN tunnel current is used. In a writing control operation thereof, a method of executing a program operation and an accompanying verify operation repeatedly by stepping up the writing pulse is used. Here, the writing time is determined mostly by difference between memory cells to be written at high-speed and memory cells to be written at low speed in the speed of their threshold voltage shift, and the width by which the writing pulse is stepped up.

Specifically, the number of writing cycles necessary for writing a desired threshold distribution is obtained by dividing the width of threshold distribution generated by one writing pulse (this width represents the difference between memory cells in the writing speed) by the step width of the writing pulse (step-up voltage). The writing time is substantially proportional to the number of writing cycles. In binary data storage, the threshold voltage needs to be shifted from an erased state to only one kind of data-written state. Therefore, the threshold level range allowable as the data-written state is wide, and hence writing can be executed with relatively high step-up voltages.

However, in multi-value data storage, e.g., four-value data storage, three data-written states need to be generated from an erased state in accordance with the data to be written. Therefore, the threshold level range assigned to one data-written state is narrow. Therefore, the writing operation needs to be executed by shifting the threshold little by little with low step-up voltages. Hence, the number of writing cycles is increased from the number required in the binary data storage, and the writing time becomes long.

Further, increase in capacitance coupling noise between adjoining memory cells (particularly, capacitance coupling noise between floating gates) due to miniaturization of the memory cell array is a large factor that hinders acceleration of the writing speed of the flash memory. Particularly, in the multi-value data storage system, the interval between threshold voltage distributions needs to be smaller than that in the binary data storage system, and hence capacitance coupling noise greatly influences the writing speed. In order to reduce the influence of capacitance coupling noise, it is necessary to lower the step-up voltages.

Conventionally, fast writing techniques for flash memories particularly of a multi-value data storage type have been proposed. According to one method, fast memory cells having a high writing speed and slow memory cells having a low writing speed are discriminated beforehand, and based on this discrimination, application of a relatively low writing pulse to the fast memory cells, application of a relatively high writing pulse to the slow memory cells, and verify operation for all the memory cells are executed. According to this method, it is possible not only to apply effective writing pulses to the fast memory cells and the slow memory cells in parallel, but also to execute a verify operation simultaneously.

However, when applying different writing pulses intermittently as in this technique, times are required for the writing pulses to rise and fall, raising a problem that the time necessary for the writing operation is increased proportionately.

### BRIEF DESCRIPTION OF THE DRAWINGS

FIG. 1 is a diagram showing a memory core configuration of a flash memory according to a first embodiment.

FIG. 2 is a diagram showing an example method for writing four-value data in the flash memory according to the first embodiment.

FIG. 3 is a diagram showing writing pulses and verify pulses of the flash memory according to the first embodiment.

FIG. 4 shows operation waveform charts of a selected word line and bit lines of the flash memory according to the first embodiment.

FIG. 5 shows operational waveform charts of a selected word line and bit lines of a flash memory according to a second embodiment.

FIG. 6 is a diagram showing writing pulses and verify pulses of a flash memory according to a third embodiment.

FIG. 7 is a diagram showing writing pulses and verify pulses of a flash memory according to a fourth embodiment.

### DETAILED DESCRIPTION

A nonvolatile semiconductor memory device according to an embodiment includes: a memory cell array including a plurality of word lines, a plurality of bit lines, and a plurality of memory cells selected by the word lines and the bit lines to store N-value data (N being an integer equal to or larger than 3); and a writing circuit configured to apply, to the word line, a writing pulse for writing target threshold levels each corresponding to N-value data into a plurality of memory cells connected to that word line commonly and selected simultaneously, while repeatedly executing a writing cycle of bringing the bit lines connected to the memory cells to be written with the target threshold levels into a selected state until writing is finished. The writing circuit is configured to divide the pulse width of the writing pulse into a plurality of sections to change the pulse height among the sections such that the respective sections provide writing voltages for writing different target threshold levels, while bringing the bit line connected to the memory cell to be written with any of the target threshold levels into a writable selected state synchronously with the section to apply the writing voltage for writing that target threshold level.

Embodiments of nonvolatile semiconductor memory device will now be explained in detail with reference to the drawings.

### First Embodiment

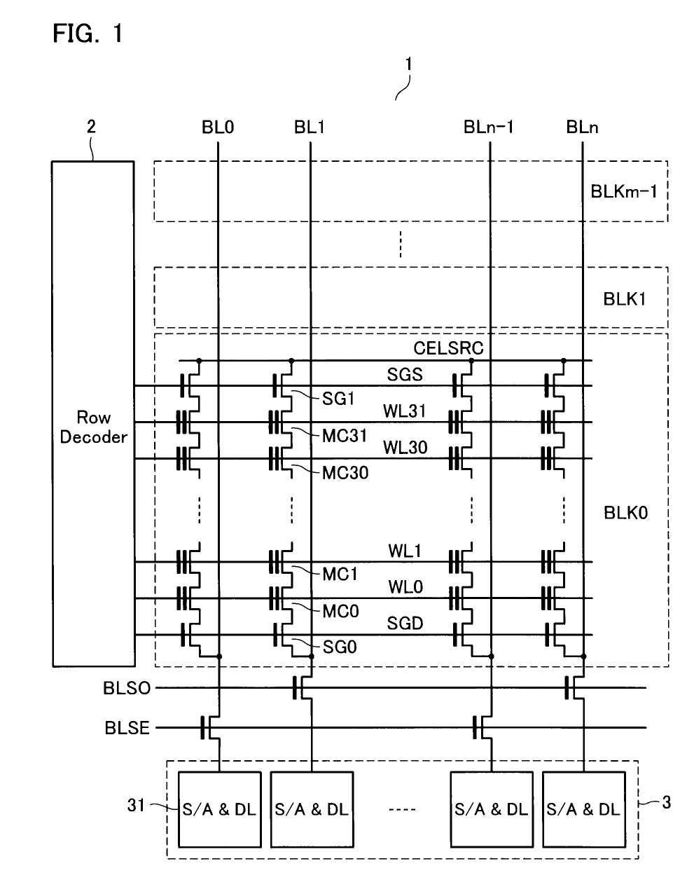

FIG. 1 shows a memory core configuration of a multi-value NAND type flash memory according to a first embodiment. A memory cell array 1 is configured as an array of NAND cell units (NAND strings) each including a plurality of electrically rewritable nonvolatile memory cells MC0 to MC31 connected in series.

One end of each NAND cell unit is connected to a bit line BL via a select gate transistor SG0, and the other end thereof is connected to a source line CELSRC via a select gate transistor SG1. The control gates of the memory cells MC0 to MC31 in the NAND cell unit are connected to different word lines WL0 to WL31. The gates of the select gate transistors SG0 and SG1 are connected to select gate lines SGD and SGS extending in parallel with the word lines WL.

There is provided a row decoder 2, which is a part of a writing circuit for selecting and driving the word lines WL and the select gate lines SGD and SGS. Each bit line BL is connected to a sense amplifier and data latch 31 in a sense amplifier circuit 3, which is a part of the writing circuit.

In the case shown here, the bit lines BL are connected in one-to-one correspondence to the sense amplifier and data latches 31. In this case, the memory cells selected by one word line WL is defined as one page to which writing/erasing is executed simultaneously.

However, in principle, the system may be configured such that, for example, an even-number bit line and an odd-number bit line which adjoin each other may share one sense amplifier and data latch. In this case, half of the memory cells selected by one word line are the unit of simultaneous writing/reading.

An aggregate of NAND cell units sharing word lines configure a block, which is a unit of data erasing. As illustrated, a plurality of blocks BLK0, BLK1, . . . , BLKm−1 are arranged in the direction along the bit lines BL.

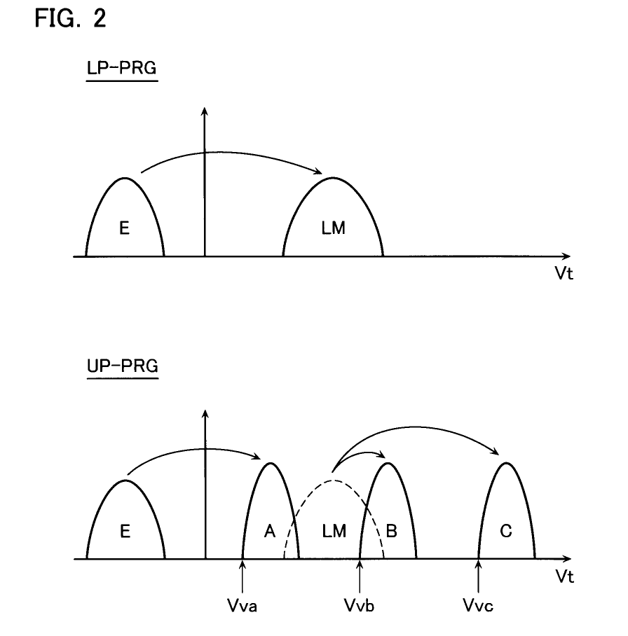

FIG. 2 shows a data writing method for when the NAND type flash memory according to the present embodiment is a four-value data storage type.

Four-value data is defined by a data state (erased state) E having a negative threshold voltage and data states A, B, and C having positive threshold voltages. Hereinafter, the data states defined by the threshold voltages will sometimes be referred to as “threshold levels” or simply “levels”.

To write four-value data, all memory cells in a selected block are set to the level E having a negative threshold voltage. This operation is data erasing. The data erasing is executed by supplying a positive erasing voltage to a p-type well in which the cell array is formed so that all word lines in the selected block become 0V and electrons are discharged from the floating gates of all the memory cells.

Then, lower page writing LP(Lower Page)-PRG is executed to write some of the memory cells having the level E up to an intermediate level LM between the levels A and B. After this, upper page writing UP (Upper Page)-PRG is executed to raise the threshold voltages from the level E to the level A, and from the intermediate level LM to the levels B and C.

The above data writing is executed as an operation of injecting electrons selectively into the floating gates of the memory cells by supplying a writing voltage to a selected word line, supplying a writing pass voltage to non-selected word lines, and supplying a voltage Vss (when raising the threshold voltage to write “0”) or a voltage Vdd (when not raising the threshold voltage to prohibit writing) to the bit lines.

That is, when writing “0”, electrons are injected from the channel of a selected cell of a NAND cell unit into the floating gate thereof under the effect of a tunnel current when the voltage Vss supplied to the bit line is transferred to the channel and the writing voltage is supplied. When writing “1” (when prohibiting writing), the NAND cell channel is charged to Vdd-Vt (Vt is a threshold voltage of the select gate transistor) to be brought into a floating state, such that when the writing voltage is supplied, the memory cell channel is boosted due to capacitance coupling with the control gate to cause no electron injection.

In the data writing, a step-up writing method of raising the writing voltage little by little at the turns of writing cycles is usually used.

Next, operation waveforms of the present embodiment will be explained.

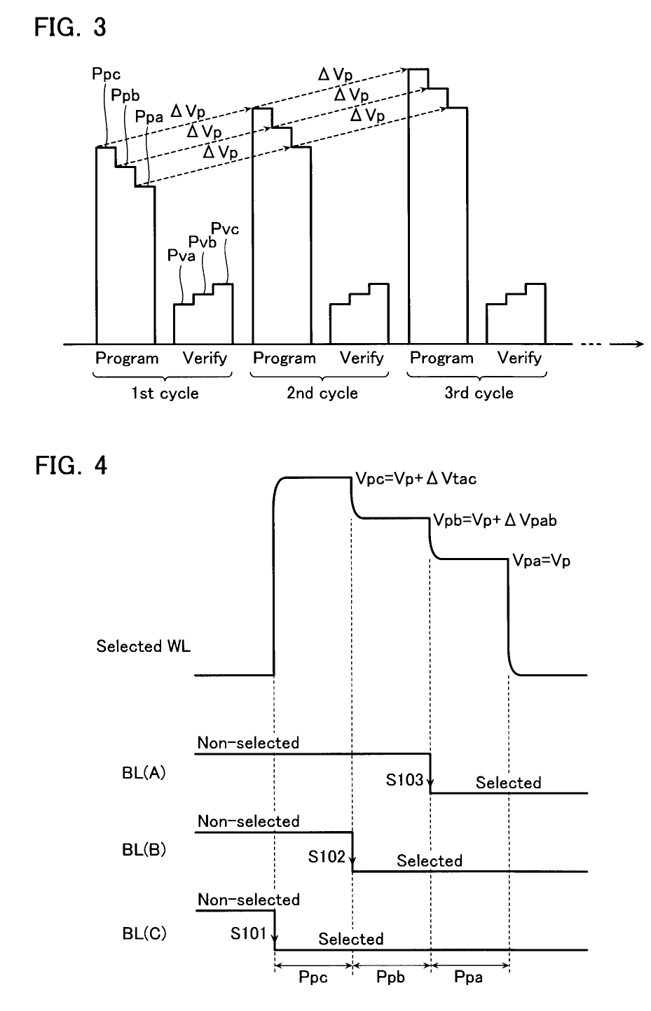

FIG. 3 is a diagram showing writing pulses and verify pulses of the present embodiment. FIG. 4 shows operation waveform charts of a selected word line and bit lines. In the following explanation, the memory cells MC to be written with the levels A, B, and C will be referred to as memory cells MC(A), MC(B), and MC(C) respectively, and the bit lines BL to select such memory cells MC(A), MC(B), and MC(C) will be referred to as bit lines BL(A), BL(B), and BL(C) respectively.

Here, it is assumed that lower page writing for wiring the intermediate level LM has already been finished for memory cells MC(B) and MC(C).

In upper page writing, writing cycles each including a program operation and a verify operation are repeatedly executed by stepping up the writing pulse applied to the selected word line WL as shown in FIG. 3.

In a program operation, one writing pulse is supplied to the selected word line WL. The pulse width of this writing pulse is divided into three continuous sections Ppa to Ppc. The section Ppa is a section having such a pulse height with which the writing pulse becomes a writing voltage Vpa (=Vp) for writing the level A. The section Ppb is a section having such a pulse height with which the writing pulse becomes a writing voltage Vpb for writing the level B. In FIG. 4, the voltage Vpb is indicated as “Vp+ΔVtab”, where ΔVtab is the difference between the level B and the adjoining level A in the threshold voltage distribution. However, the voltage Vpb is not limited to this. The section Ppc is a section having such a pulse height with which the writing pulse becomes a writing voltage Vpc for writing the level C. In FIG. 4, the voltage Vpc is indicated as “Vp+ΔVtac”, where ΔVtac is the difference between the level A and the level C in the threshold voltage distribution. These sections Ppa to Ppc are arranged in the order of the sections Ppc, Ppb, and Ppa, because the pulse height is changed from higher levels to lower levels.

The bit lines BL(A), BL(B), and BL (C) are selected at the timings at which the sections Ppa to Ppc for writing the levels A, B, and C respectively start. Specifically, the bit lines are selected as follows.

First, the bit line BL(C) is lowered from a non-selected level to a selected level at the same timing as the start of the first section Ppc of the writing pulse (step S101). The bit lines BL(B) and BL(A) remain at a non-selected level during the section Ppc.

Next, the bit line BL(B) is lowered from a non-selected level to a selected level at the same timing as the start of the section Ppb (step S102). At this time, the bit line BL(C) is kept at the selected level, because when instead raising the bit line BL(C) to the non-selected level again, it is necessary for the selected word line WL to rise again because the non-selecting voltage in the boosted NAND channel has already vanished in step S101. When the bit line BL(C) is kept at the selected level in this way, the level B is written into the memory cell MC(C). However, even in this case, influence caused by the level B being written into the memory cell MC(C) written with the level C is small. That is, by sufficiently separating the threshold voltage distributions of the levels B and C, it is possible to avoid erroneous data writing. Meanwhile, the bit line BL(A) remains at a non-selected level during the section Ppb.

Last, the bit line BL(A) is lowered from a non-selected level to a selected level at the same timing as the start of the section Ppa (step S103). At this time, the bit lines BL(C) and BL(B) are kept at the selected level.

In a verify operation, one verify pulse is supplied to the selected word line WL. The pulse width of the verify pulse is also divided into three continuous sections Pva, Pvb, and Pvc. The pulse heights of the verify pulse in the sections Pva, Pvb, and Pvc are verify voltages Vva, Vvb, and Vvc for verifying the levels A, B, and C shown in FIG. 2 respectively.

Data writing is finished by repeating writing cycles each including the above program operation and verify operation by stepping up the writing pulse by a certain voltage ΔVp.

One conventional method applies a writing pulse having a uniform pulse height to a selected word line WL repeatedly by stepping up the writing pulse. In this example, when it is assumed that the number of writing cycles necessary for writing the level A having the lowest threshold voltage is n, larger numbers of writing cycles are necessary for writing the levels B and C having higher threshold voltages than the level A.

Another conventional method applies a writing pulse similar to that of the first conventional method repeatedly, while skipping the verify operation for any level that has been finished with being written earlier. This method can reduce the time necessary for the verify operation from the time necessary in the first conventional method, but this does not mean that the number of writing cycles is reduced.

In this regard, according to the present embodiment, since one writing pulse is divided into sections Ppa, Ppb, and Ppc having pulse heights optimum for the levels A, B, and C, these levels are written with the same number of writing cycles n, even though they are different threshold voltages. As a result, the total number of writing cycles necessary for data to be written into the memory cells MC can be reduced.

Hence, according to the present embodiment, it is possible to provide a flash memory which can execute data writing faster than the above conventional examples.

### Second Embodiment

The second embodiment is another example of the first embodiment modified in the program operation, and identical with the first embodiment except the operation waveforms of the bit lines.

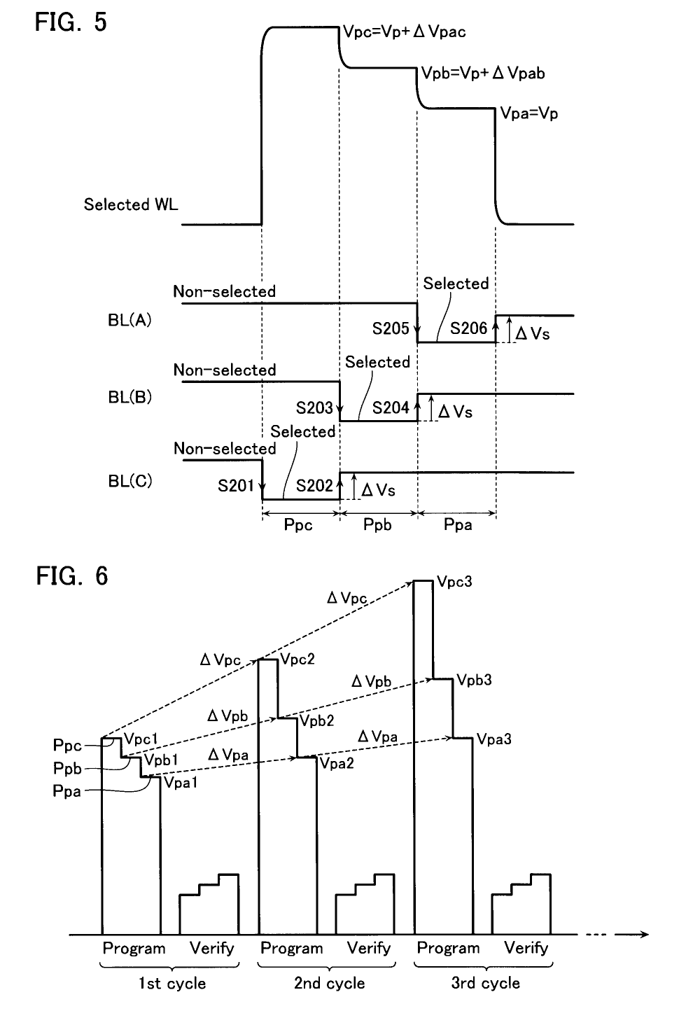

FIG. 5 shows operation waveform charts of a selected word line WL and bit lines BL according to the present embodiment. Since the operation of the selected word line WL is the same as the first embodiment shown in FIG. 4, explanation will not be given thereon.

First, a bit line BL(C) is lowered from a non-selected level to a selected level at the same timing as the start of the first section Ppc of a writing pulse (step S201). During the section Ppc, the bit lines BL(B) and BL(A) remain at a non-selected level.

Next, at the same timing as the end of the section Ppc (the start of the section Ppb), the bit line BL(C) is raised from the selected level by a voltage ΔVs (step S202), and the bit line BL(B) is lowered from a non-selected level to a selected level (step S203). During the section Ppb, the bit line BL(A) remains at a non-selected level.

Then, at the same timing as the end of the section Ppb (the start of the section Ppa), the bit line BL(B) is raised from the selected level by the voltage ΔVs (step S204), and the bit line BL(A) is lowered from a non-selected level to a selected level (step S205).

Last, at the same timing as the end of the section Ppa, the bit line BL(A) is raised from the selected level by the voltage ΔVs (step S206). During the section Ppa, the bit lines BL(C) and BL(B) are kept at the potential higher than the selected level by the voltage ΔVs.

According to the first embodiment shown in FIG. 4, the bit line once lowered to the selected level is kept at the selected level even after the section for writing a desired level ends. Therefore, the memory cell is left in the selected state even when writing of a subsequent different threshold level is executed, and hence the threshold voltage of this memory cell might shift.

In this regard, according to the present embodiment, the bit line is brought into the selected state only during the section in which writing of a desired threshold level is executed. After this, the bit line is changed to a potential between the selected level and the non-selected level. Therefore, influence to be given on the program operation in the subsequent section can be reduced.

That is, according to the present embodiment, it is possible to provide a flash memory which not only can obtain the same effect as that of the first embodiment, but also can reduce erroneous data writing.

### Third Embodiment

The third embodiment is another example of the first embodiment modified in the program operation, and identical with the first embodiment except the step width of the writing pulse (step width is the width of increase in the pulse height).

FIG. 6 is a diagram showing writing pulses and verify pulses according to the present embodiment. Since verify pulses are the same as those of the first embodiment shown in FIG. 3, explanation will not be given thereon.

According to the present embodiment, the step widths between the writing pulse of a given writing cycle and the writing pulse of the next writing cycle are voltages ΔVpa, ΔVpb, and ΔVpc, which are varied among the different sections Ppa to Ppc.

In FIG. 6, the step widths ΔVpa to ΔVpc are in the relationship of “ΔVpc>ΔVpb>ΔVpa”. However, the step widths are not limited to this relationship, but optimum step widths may be set for the respective threshold levels.

In FIG. 6, the step widths between the writing pulse of the first cycle and the writing pulse of the second cycle are equal to the step widths between the writing pulse of the second cycle and the writing pulse of the third cycle. However, the step widths may be changed at each turn of the writing cycle.

If the same step width is used for all the threshold levels between any writing pulses as in the first embodiment, it becomes difficult to adjust the number of writing cycles necessary for finishing data writing, threshold-level by threshold-level.

In this regard, according to the present embodiment, it is possible not only to obtain the same effect as that of the first embodiment, but also to facilitate adjusting the number of writing cycles necessary for finishing data writing, because the step widths of the writing pulses can be set optimally threshold-level by threshold-level. As a result, it becomes possible to provide a flash memory that can reduce unnecessary writing cycles and hence execute data writing still faster.

### Fourth Embodiment

The fourth embodiment is another example of the first embodiment modified in the data writing operation, and identical with the first embodiment except the writing pulses and verify pulses of the respective writing cycles.

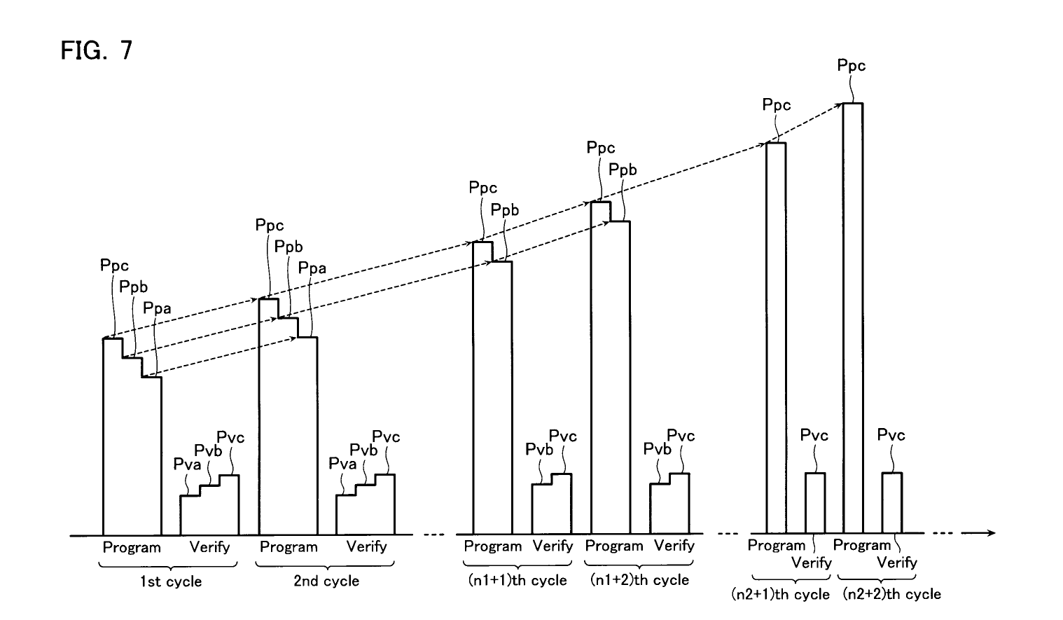

FIG. 7 is a diagram showing writing pulses and verify pulses according to the present embodiment.

According to the present embodiment, the section for writing any threshold level confirmed in the verify operation of a given writing cycle to have been finished with being written is omitted from the program operation and verify operation of the following writing cycles.

In FIG. 7, data writing on the memory cells MC(A), MC(B), and MC(C) has not been finished in the first cycle. Therefore, after a writing pulse made up of the sections Ppc, Ppb and Ppa for writing the levels C, B, and A is applied, a verify pulse made up of the sections Pva, Pvb, and Pvc for verifying the levels A, B, and C is applied. Writing cycles similar to the first cycle are repeated up to an (n1)th cycle in which data writing on the memory cell MC(A) is finished.

Then, in the (n1+1)th cycle, the program operation and the verify operation are executed on the memory cells MC(B) and MC(C) except the memory cell MC(A) finished with data writing in the (n1)th cycle. Hence, the writing pulse includes no section Ppa but only the sections Ppc and Ppb. The verify pulse includes no section Pva but only the sections Pvb and Pvc. That is, the process time per cycle is reduced from the time required in the (n1)th cycle by what corresponds to the sections Ppa and Pva. Writing cycles similar to this (n1+1)th cycle are repeated up to an (n2)th cycle in which data writing on the memory cell MC(B) is finished.

Next, in the (n2+1) th cycle, the program operation and the verify operation are executed on the memory cell MC(C) not finished with data writing by the (n2) th cycle. Hence, the writing pulse includes only the section Ppc with the section Ppb further omitted. The verify pulse includes only the section Pvc with the section Pvb further omitted. That is, the process time per cycle is reduced from the time required in the (n2)th cycle by what corresponds to the sections Ppb and Pvb. Writing cycles similar to the (n2+1)th cycle are repeated until data writing on the memory cell MC(C) is finished.

Hence, according to the present embodiment, it is possible not only to obtain the same effect as that of the first embodiment, but also to provide a flash memory that can reduce the process time for data writing from the time required in the first embodiment, because the program operation and the verify operation are skipped for those memory cells finished with data writing earlier.

Others

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in the above explanation, a flash memory using memory cells for four-value data storage has been employed. However, the present invention can also be applied to a flash memory using memory cells that can store data of a larger multi-value.

In the above embodiments, the selected level of the bit lines is constant. However, it is possible to adjust the selected level. In this case, sensitive data writing that may become necessary in the later part of the data writing operation can be realized.

What is claimed is:

1. A nonvolatile semiconductor memory device, comprising:
a memory cell array including a plurality of word lines, a plurality of bit lines, and a plurality of memory cells selected by the word lines and the bit lines to store N-value data (N being an integer equal to or larger than 3); and
a writing circuit configured to apply, to the word line, a writing pulse for writing target threshold levels each corresponding to N-value data into a plurality of memory cells connected to that word line commonly and selected simultaneously, while repeatedly executing a writing cycle of bringing the bit lines connected to the memory cells to be written with the target threshold levels into a selected state until writing is finished,
the writing circuit being configured to divide a pulse width of the writing pulse into a plurality of sections to change a pulse height among the sections such that the respective sections provide writing voltages for writing different target threshold levels, while bringing the bit line connected to the memory cell to be written with any of the target threshold levels into a writable selected state synchronously with the section for applying the writing voltage for writing that target threshold level.

2. The nonvolatile semiconductor memory device according to claim 1,
wherein the writing circuit brings the bit line into the selected state only for a period in which writing is executed on the memory cell connected to that bit line.

3. The nonvolatile semiconductor memory device according to claim 1,
wherein the writing circuit increases the pulse height of the writing pulse at each turn between writing cycles, and a width of increase of the pulse height of the writing pulse is varied among the target threshold levels.

4. The nonvolatile semiconductor memory device according to claim 1,
wherein the writing circuit applies a verify pulse for verify reading to the word line subsequently to application of the writing pulse, while dividing a pulse width of the verify pulse into a plurality of sections to change a pulse height among the sections such that the respective sections provide verify voltages for different target threshold levels, and skips the sections for applying the writing pulse and the verify pulse corresponding to any target threshold level to the word line if writing of that target threshold level has been finished.

5. The nonvolatile semiconductor memory device according to claim 1,
wherein the writing circuit changes the bit line from the selected state to a voltage between the selected state and a non-selected state, upon finishing writing on the memory cell connected to that bit line.

6. The nonvolatile semiconductor memory device according to claim 1,
wherein in one writing pulse, a difference between the writing voltages for writing different two of the target threshold levels is equal to or greater than a difference between threshold voltages of the memory cells corresponding to the two target threshold levels respectively.

7. The nonvolatile semiconductor memory device according to claim 3,
wherein the width of increase, between two writing cycles, of the pulse height of the writing pulse is larger for higher ones of the target threshold levels.

8. A nonvolatile semiconductor memory device, comprising:
a memory cell array including a plurality of word lines, a plurality of bit lines, and a plurality of memory cells selected by the word lines and the bit lines to store N-value data (N being an integer equal to or larger than 3); and
a writing circuit configured to apply, to the word line, a writing pulse for writing target threshold levels each corresponding to N-value data into a plurality of memory cells connected to that word line commonly and selected simultaneously, while repeatedly executing a writing cycle of bringing the bit lines connected to the memory cells to be written with the target threshold levels into a selected state until writing is finished,
the writing circuit being configured to divide a pulse width of the writing pulse into a plurality of sections to change a pulse height of the writing pulse sequentially from higher levels to lower levels such that the respective sections provide writing voltages for writing different target threshold levels, while bringing the bit line connected to the memory cell to be written with any of the target threshold levels into a writable selected state synchronously with the section for applying the writing voltage for writing that target threshold level.

9. The nonvolatile semiconductor memory device according to claim 8,
wherein the writing circuit brings the bit line into the selected state only for a period in which writing is executed on the memory cell connected to that bit line.

10. The nonvolatile semiconductor memory device according to claim 8,
wherein the writing circuit increases the pulse height of the writing pulse at each turn between writing cycles, and a width of increase of the pulse height of the writing pulse is varied among the target threshold levels.

11. The nonvolatile semiconductor memory device according to claim 8,
wherein the writing circuit applies a verify pulse for verify reading to the word line subsequently to application of the writing pulse, while dividing a pulse width of the verify pulse into a plurality of sections to change a pulse height among the sections such that the respective sections provide verify voltages for different target threshold levels, and skips the sections for applying the writing pulse and the verify pulse corresponding to any target threshold level to the word line if writing of that target threshold level has been finished.

12. The nonvolatile semiconductor memory device according to claim 8,
wherein the writing circuit changes the bit line from the selected state to a voltage between the selected state and a non-selected state, upon finishing writing on the memory cell connected to that bit line.

13. The nonvolatile semiconductor memory device according to claim 8,
wherein in one writing pulse, a difference between the writing voltages for writing different two of the target threshold levels is equal to or greater than a difference between threshold voltages of the memory cells corresponding to the two target threshold levels respectively.

14. The nonvolatile semiconductor memory device according to claim 10,
wherein the width of increase, between two writing cycles, of the pulse height of the writing pulse is larger for higher ones of the target threshold levels.

15. A nonvolatile semiconductor memory device, comprising:
a memory cell array including a plurality of word lines, a plurality of bit lines, and a plurality of memory cells selected by the word lines and the bit lines to store N-value data (N being an integer equal to or larger than 3); and
a writing circuit configured to apply, to the word line, a writing pulse for writing target threshold levels each corresponding to N-value data into a plurality of memory cells connected to that word line commonly and selected simultaneously, while repeatedly executing a writing cycle of bringing the bit lines connected to the memory cells to be written with the target threshold levels into a selected state until writing is finished,
the writing circuit being configured to divide a pulse width of the writing pulse into a plurality of sections to change a pulse height among the sections such that the respective sections provide writing voltages for writing different target threshold levels, while bringing the bit line connected to the memory cell to be written with a certain target threshold level into a non-writable non-selected state in the section for applying the writing voltage for writing another target threshold level higher than that certain target threshold level.

16. The nonvolatile semiconductor memory device according to claim 15,
wherein the writing circuit brings the bit line into the selected state only for a period in which writing is executed on the memory cell connected to that bit line.

17. The nonvolatile semiconductor memory device according to claim 15,
wherein the writing circuit increases the pulse height of the writing pulse at each turn between writing cycles, and a width of increase of the pulse height of the writing pulse is varied among the target threshold levels.

18. The nonvolatile semiconductor memory device according to claim 15,
wherein the writing circuit applies a verify pulse for verify reading to the word line subsequently to application of the writing pulse, while dividing a pulse width of the verify pulse into a plurality of sections to change a pulse height among the sections such that the respective sections provide verify voltages for different target threshold levels, and skips the sections for applying the writing pulse and the verify pulse corresponding to any target threshold level to the word line if writing of that target threshold level has been finished.

19. The nonvolatile semiconductor memory device according to claim 15,
wherein the writing circuit changes the bit line from the selected state to a voltage between the selected state and a non-selected state, upon finishing writing on the memory cell connected to that bit line.

20. The nonvolatile semiconductor memory device according to claim 17,
wherein in one writing pulse, a difference between the writing voltages for writing different two of the target threshold levels is equal to or greater than a difference between threshold voltages of the memory cells corresponding to the two target threshold levels respectively.
